(19) United States
(12) Patent Application Publication
(10) Pub. No.: US 2020/0075786 A1
(43) Pub. Date: Mar. 5, 2020

(54) PHOTODIODE AND METHOD FOR MANUFACTURING THE SAME

(71) Applicant: TYNTEK CORPORATION, HSINCHU CITY (TW)

(72) Inventors: JUN-CHIEH HUANG, HSINCHU CITY (TW); CHIA-HSIANG CHOU, HSINCHU CITY (TW)

(21) Appl. No.: 16/170,443

(22) Filed: Oct. 25, 2018

(30) Foreign Application Priority Data
Aug. 29, 2018 (TW) 107130142

(51) Int. Cl. H01L 31/0352; H01L 31/0216; H01L 31/18

(52) U.S. Cl. CPC H01L 31/035281; H01L 31/03046; H01L 31/1844; H01L 31/02161

(57) ABSTRACT

A photodiode includes a substrate having a lateral side having an inclined light incidence surface that forms an angle of 45 or 60 degrees with respect to a normal of the substrate; and an epitaxial layer disposed on the substrate. A method for manufacturing a photodiode is provided, including: providing a substrate; forming an epitaxial layer on the substrate; and making a lateral side of the substrate an inclined light incidence surface that forms an angle of 45 or 60 degrees with respect to a normal of the substrate. Another method is also provided, including: providing a substrate; forming an etch stop layer on the substrate; forming an epitaxial layer on the etch stop layer; and applying an agent to etch a lateral side of the substrate to form an inclined light incidence surface having an angle of 45 or 60 degrees with respect to a normal of the substrate.

### FIELD OF THE INVENTION

The present invention relates to a photodiode and a method for manufacturing the photodiode, and more particular to a photodiode that improves responsivity of sideway light reception and a method for manufacturing the photodiode.

### BACKGROUND OF THE INVENTION

A photodiode is a semiconductor device that converts an optical signal into an electrical signal. Commonly known photodiodes include PN photodiodes, PIN photodiodes, and avalanche photodiodes.

Taking a PN photodiode as an example, the working principle of the photodiode is that reverse bias is applied to a PN junction and an electric field is built therein, wherein with light irradiating on a depletion zone of the PN junction, energy is transferred from photons to a bonded electron so that the electron may overcome an energy gap to leap from the valence band to the conduction band. Once the electron moves to the conduction band, a hole is generated in the valence band to thereby form an electron-hole pair. The electron and hole are driven by the electric field to generate a photocurrent so as to output a voltage to an external circuit and a load to complete a process of conversion from an optic signal to an electric signal.

However, known photodiodes are mostly based on front-side light coupling or back-side light coupling. Although a few photodiodes are structures for later-side light coupling, they are suffering insufficient responsivity due to small light receiving areas and may not be effective in converting light from lateral sides when serving as a photo-detector.

### SUMMARY OF THE INVENTION

Thus, it is desired to provide an invention that overcomes the above problems.

A technical solution that this invention adopts to overcome the problems of the prior art is providing a photodiode, which comprises: a substrate, the substrate having a lateral side forming a light incidence surface that is inclined, the light incidence surface and a normal of the substrate forming therebetween an included angle of 45 degrees or 60 degrees; and an epitaxial layer, which is disposed on the substrate.

In an embodiment of the photodiode according to the present invention, an etch stop layer is further included, and the etch stop layer is disposed between the substrate and the epitaxial layer.

In an embodiment of the photodiode according to the present invention, an anti-reflection layer is disposed on the epitaxial layer, and the anti-reflection layer comprises a metallic alloy.

In an embodiment of the photodiode according to the present invention, the metallic alloy comprises Ti, Pt, Au and AuGeNi.

The present invention also provides a method for manufacturing a photodiode, which comprises: providing a substrate; forming an epitaxial layer on the substrate; and making a lateral side of the substrate form a light incidence surface, the light incidence surface and a normal of the substrate forming therebetween an included angle of 45 degrees or 60 degrees.

In an embodiment of the above method, an operation of forming the inclined light incidence surface comprises cutting with machine processing.

In an embodiment of the above method, an operation of forming the inclined light incidence surface comprises first cutting a P-type semiconductor of the epitaxial layer to a predetermine depth with machine processing and then applying a chemical agent to carry out etching to form the light incidence surface.

In an embodiment of the above method, forming an anti-reflection layer on the epitaxial layer is further included, and the anti-reflection layer comprises a metallic alloy.

In an embodiment of the above method, the metallic alloy comprises Ti, Pt, Au and AuGeNi.

The present invention further provides a method for manufacturing a photodiode, which comprises: providing a substrate; forming an etch stop layer on the substrate; forming an epitaxial layer on the etch stop layer; and applying a chemical agent to etch a lateral side of the substrate to form a light incidence surface that is inclined, the light incidence surface and a normal of the substrate forming therebetween an included angle of 45 degrees or 60 degrees.

In an embodiment of the above method, forming an anti-reflection layer on the epitaxial layer is further included, and the anti-reflection layer comprises metallic alloy.

In an embodiment of the above method, the metallic alloy comprises Ti, Pt, Au and AuGeNi.

With the technical solution of this invention, a photodiode and a method for manufacturing the photodiode are proposed, in which a light incidence surface that is formed on a lateral side of a substrate and is made inclined is provided to achieve extremely high responsivity of the photodiode for lateral-side light coupling, and a much wider range of application can be realized.

### BRIEF DESCRIPTION OF THE DRAWINGS

FIG. 1A is a schematic view showing a photodiode according to an embodiment of the present invention;

FIG. 1B is a schematic view showing a photodiode according to another embodiment of the present invention;

FIG. 2A is a schematic view illustrating lateral-side light coupling of the photodiode according to the present invention;

FIG. 2B is a schematic view illustrating lateral-side light coupling of the photodiode according to the present invention showing a different inclination arrangement of a light incidence surface;

FIG. 3 is a flow chart illustrating a method for manufacturing a photodiode according to an embodiment of the present invention; and

FIG. 4 is a flow chart illustrating a method for manufacturing a photodiode according to another embodiment of the present invention.

### DETAILED DESCRIPTION OF THE PREFERRED EMBODIMENTS

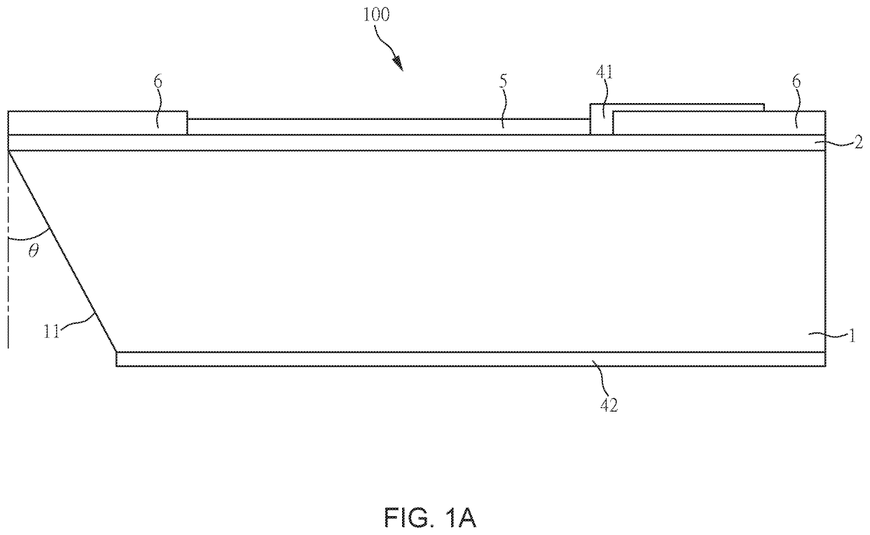

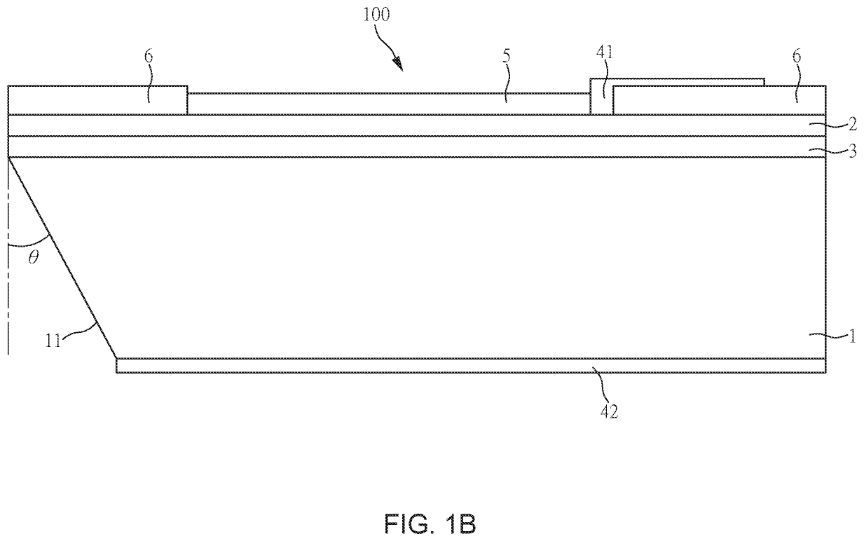

Embodiments of the present invention will be described with reference to FIGS. 1A-4. These drawings and the description are provided to facilitate understanding of this invention and are just some of the embodiments of this invention and are not to be construed as constraint to the embodiments of this invention.

Referring to FIG. 1A, a photodiode 100 is disclosed, comprises: a substrate 1 and an epitaxial layer 2.

The substrate 1 is made of a material comprising a compound semiconductor, such as InP and GaAs.

The epitaxial layer 2 is disposed on a top of the substrate 1 and comprises P-type semiconductor and N-type semiconductor. The epitaxial layer 2 is made of a material comprising AlGaAs, AlAs, InGaAs, or GaAsP. In an embodiment, the P-type semiconductor is formed in the N-type semiconductor with a diffusion process.

The substrate 1 has a lateral side that forms an light incidence surface 11 that is an inclined or slope surface. As shown in FIGS. 1A and 1B, the light incidence surface 11 and a normal of the substrate 1 form therebetween an included angle, θ, which is 45 degrees or 60 degrees.

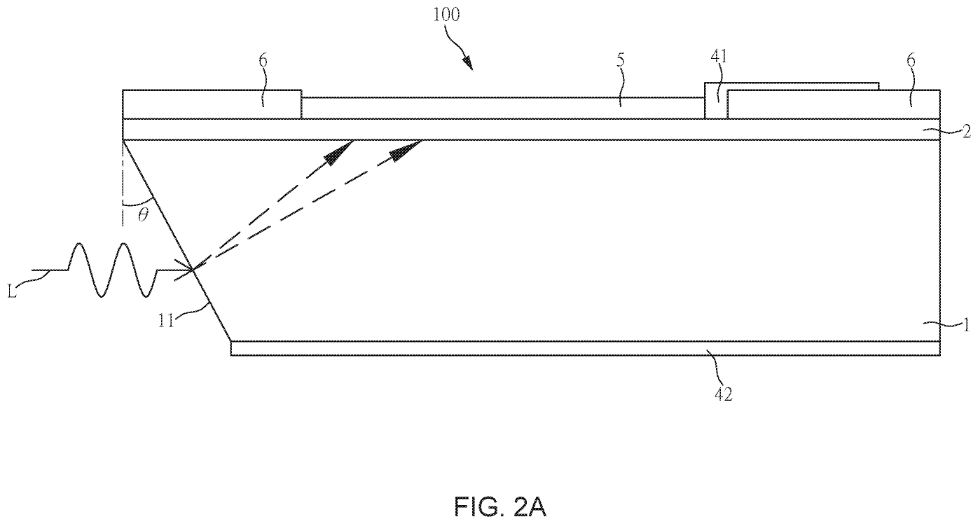

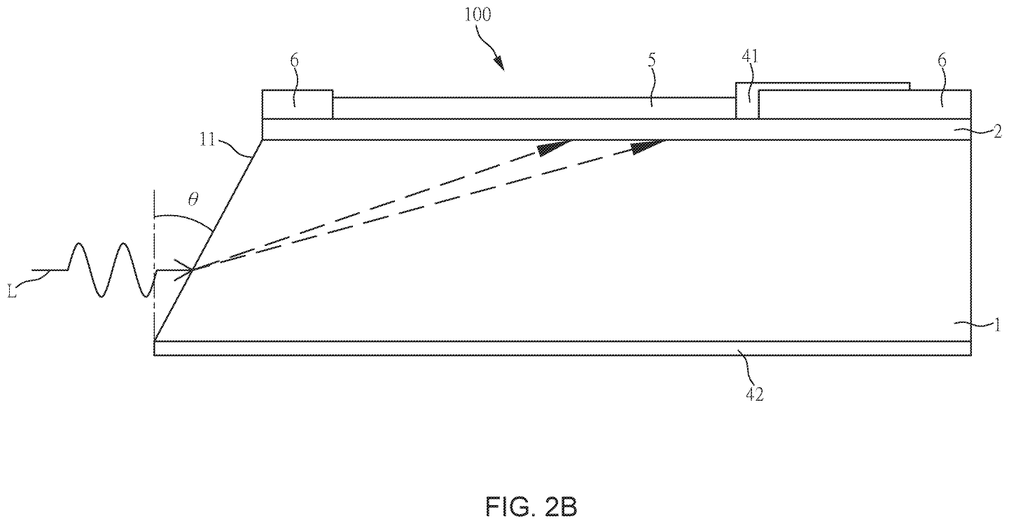

The inclined light incidence surface 11 allows the photodiode 100 to show excellent responsivity in lateral-side light coupling (as shown in FIG. 2A). The term responsivity of the photodiode is defined as a current generated in response to an input of unit power of light and carries a unit of A/W. Fora conventional photodiode, which has no modification made to a substrate thereof, a light incidence surface is parallel to a normal of the substrate, having 0 degree therebetween, and the responsivity is 0.01 A/W; however, for the photodiode 100 according to the present invention, as shown in FIG. 2A, the light incidence surface 11 is made as an inclined or slope surface so that light L, after getting incident to the light incidence surface 11, would be subjected to refraction and is internally reflected to reach a light absorption layer of the epitaxial layer 2 to generate a photocurrent. Specifically, when the included angle θ is 60 degrees, responsivity reaches 0.5 A/W or higher; and when the included angle θ is 45 degrees, the responsivity is 0.65 A/W or higher.

It is noted here that the inclined light incidence surface 11 can be arranged to selectively incline in two different directions. Taking the direction in which the substrate 1 points to the epitaxial layer 2 as a reference, the inclined light incidence surface 11 can be leftward inclination (as shown in FIG. 2A) or rightward inclination (as shown in FIG. 2B). For easy reference for description, through the entire disclosure, the term “included angle θ” is used to designate the included between the inclined light incidence surface 11 and the normal of the substrate 1, and two different ways of inclination are as those shown in the drawings.

When the light incidence surface 11 is in the form of leftward inclination as shown in FIG. 2A, light L coming from the left side, after refraction, would reach a location at a middle, rear side (close to light source) . When the light incidence surface 11 is in the form of rightward inclination as shown in FIG. 2B, light L coming from the left side, after refraction, would reach a location at a middle, front side (away from light source). In this disclosure, the terms concerning position, inclination direction, location of light source are used to designate relative positions of parts and this invention should not be limited by such terms.

The light incidence surface 11 of the substrate 1 can be formed through machining or machine processing. In an embodiment, a diamond cutter is used to cut the substrate 1 to form the light incidence surface 11. An advantage of adopting machining or machine processing is that formation of a desired angle is easy, better stability can be achieved, concerns about uniformity are reduced, and an outside surface is flat and generally free of defects and issues of mold detachment.

Optionally, the light incidence surface 11 of the substrate 1 can alternatively formed through etching with chemicals. When chemicals etching is adopted to form the light incidence surface 11, it is preferable, as shown in FIG. 1B, the photodiode 100 further comprises an etch stop layer 3. The etch stop layer 3 is formed between the substrate 1 and the epitaxial layer 2. The etch stop layer 3 provide protection for preventing undesired damage to the structure of the epitaxial layer 2 due to irregular depth of etching. In some embodiments, the etch stop layer 3 is made of a material comprising InGaAs, InGaP, or InGaAsP.

The epitaxial layer 2 and the etch stop layer 3 can be formed with metal organic chemical vapor deposition (MOCVD), atomic layer deposition (ALD), or a combination thereof.

In some embodiments, chemicals that are adopted of carry out etching of the substrate 1 can be HCl, HBr, HNO₃, H₃PO₄, NH₄OH, H₂O₂, and H₂SO₄, and different chemicals must be selected according to different material properties of the substrate 1, such as crystal lattice orientation, to carry out etching of the substrate 1. For example, when the substrate 1 is formed of a material of InP, HCl and H₃PO₄ having a ratio of 1:3 can be used to carry out the etching; when the substrate 1 is made of a material of GaAs, then NH₄OH, H₂O₂ and H₂O having a ratio of 1:1:1 can be used to etch the substrate 1.

Optionally, the light incidence surface 11 of the substrate 1 can be formed by sequentially applying machine processing and etch forming such that before the light incidence surface 11 is formed, machine processing is applied to cut the P-type semiconductor of the epitaxial layer 2 to a predetermined depth, and then chemical agents are added to carry out etching of the light incidence surface 11. An advantage of this process is that there is no need to form an etch stop layer 3, and the time required for etching can be reduced.

As shown in FIGS. 1A and 1B, the photodiode 100 according to the present invention is further formed with electrodes 41, 42 for connection with an external circuit to output a voltage generated by light. In an embodiment, the photodiode 100 according to the present invention comprises an anti-reflection layer 5, which is disposed on the epitaxial layer 2, such as being disposed on the P-type semiconductor of the epitaxial layer 2. The purpose of the anti-reflection layer 5 is to reduce or prevent light that has entered the semiconductor from being redirected toward outside so that light can be effectively converted in the light absorption layer of the epitaxial layer 2 to thereby improve responsivity. In conventional photodiodes, the anti-reflection layer is often made of an oxide, such as SiO₂ and SiNx, while in this invention, the anti-reflection layer 5 of the photodiode 100 is made of a metallic alloy. In an embodiment, the metallic alloy comprises Ti, Pt, Au, and AuGeNi, to provide secondary absorption of light so that compared to the conventional photodiodes, the photodiode 100 of the present invention shows higher responsivity.

As shown in FIGS. 1A and 1B, the photodiode 100 according to the present invention comprises a passivation layer 6, which is disposed on a part of a surface of the epitaxial layer 2. This part of the surface comprises an area that is not in contact engagement with or is not in connection with the anti-reflection layer 5, and the electrode 41 is disposed on the passivation layer 6 and is partly connected to the epitaxial layer 2.

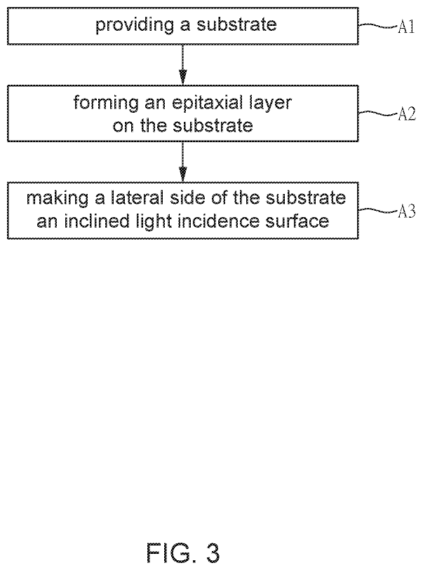

Further, the present invention also provides a method for manufacturing a photodiode, which produces a photodiode that shows excellent responsivity. A flow chart being shown in FIGS. 3, with additional reference had to FIG. 1A, the method for manufacturing a photodiode comprises: Step A1: providing a substrate 1; Step A2: forming an epitaxial layer 2 on a top of the substrate 1; and Step A3: making a lateral side of the substrate 1 inclined to form an inclined light incidence surface 11.

Materials that can be used to make the substrate 1 and the epitaxial layer 2 have been discussed above and no repeated description will be necessary herein.

A process that can be adopted in Step A3 to form the light incidence surface 11 is machining or machine processing. As noted above, in an embodiment of this invention, a diamond cutter is used to cut the substrate 1 to form the light incidence surface 11 on a lateral side thereof. In an embodiment, the light incidence surface 11 and a normal of the substrate 1 form therebetween an inclined angle of 45 degrees or 60 degrees. As noted above, when the included angle θ is 60 degrees, responsivity reaches 0.5 A/W or higher; and when the included angle θ is 45 degrees, the responsivity is 0.65 A/W or higher.

As noted above, the method for manufacturing a photodiode according to the present invention further comprises forming an anti-reflection layer 5 atop the epitaxial layer 2, and the anti-reflection layer 5 comprises a metallic alloy. In an embodiment, the metallic alloy comprises Ti, Pt, Au and AuGeNi.

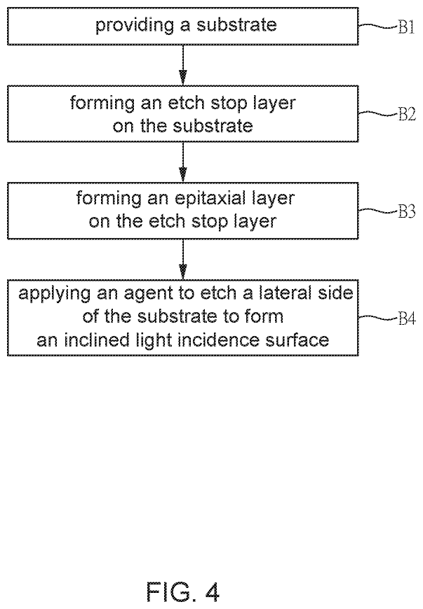

Further, the present invention further provides a method for manufacturing a photodiode, which produces a photodiode that shows excellent responsivity. A flow chart being shown in FIGS. 4, with additional reference had to FIG. 1B, the method for manufacturing a photodiode comprises: Step B1: providing a substrate 1; Step B2: forming an etch stop layer 3 on the substrate 1; Step B3: forming an epitaxial layer 2 on the etch stop layer 3; and Step B4: applying a chemical agent to etch a lateral side of the substrate 1 to form alight incidence surface 11 that is in an inclined form.

Materials that can be used to make the substrate 1, the epitaxial layer 2, and the etch stop layer 3 have been discussed above and no repeated description will be necessary herein.

The chemical agent that is adopted in Step B4 to etch the light incidence surface 11 has been discussed above, and repeated description will be omitted here. In an embodiment, the light incidence surface 11 and a normal of the substrate 1 form therebetween an inclined angle of 45 degrees or 60 degrees. As noted above, when the included angle θ is 60 degrees, responsivity reaches 0.5 A/W or higher; and when the included angle θ is 45 degrees, the responsivity is 0.65 A/W or higher.

As noted above, the method for manufacturing a photodiode according to the present invention further comprises forming an anti-reflection layer 5 atop the epitaxial layer 2, and the anti-reflection layer 5 comprises a metallic alloy. In an embodiment, the metallic alloy comprises Ti, Pt, Au and AuGeNi.

Further, the two method as described above may further comprises forming a passivation layer 6 on the epitaxial layer 2 and etching a part of the passivation layer 6 to expose the epitaxial layer 2, wherein in an embodiment, the exposed part is a P-type semiconductor area of the epitaxial layer 2, and the anti-reflection layer 5 and an electrode 41 are separately or simultaneously formed on the P-type semiconductor of the epitaxial layer 2, wherein the electrode 41 partly extends to the top of the passivation layer 6.

To summarize the above description of the embodiments, the present invention provides a photodiode and a method for manufacturing the photodiode, which make a lateral side of a substrate forming an inclined light incidence surface, so that the photodiode shows extremely high responsivity for lateral-side light coupling thereby making the application thereof wider.

What is claimed is:

1. A photodiode, comprising:
a substrate, which has a lateral side that forms an inclined light incidence surface, the light incidence surface forming an angle of 45 degrees or 60 degrees with respect to a normal of the substrate; and
an epitaxial layer, which is disposed on the substrate.

2. The photodiode according to claim 1, further comprising an etch stop layer, which is disposed between the substrate and the epitaxial layer.

3. The photodiode according to claim 1, further comprising an anti-reflection layer, which is disposed atop the epitaxial layer, the anti-reflection layer comprising a metallic alloy.

4. The photodiode according to claim 2, further comprising an anti-reflection layer, which is disposed on the epitaxial layer, the anti-reflection layer comprising a metallic alloy.

5. The photodiode according to claim 3, wherein the metallic alloy comprises Ti, Pt, Au and AuGeNi.

6. The photodiode according to claim 4, wherein the metallic alloy comprises Ti, Pt, Au and AuGeNi.

7. A method for manufacturing a photodiode, comprising:
providing a substrate;
forming an epitaxial layer on the substrate; and
making a lateral side of the substrate form a light incidence surface that is inclined, the light incidence surface forming an angle of 45 degrees or 60 degrees with respect to a normal of the substrate.

8. The method according to claim 7, wherein an operation of forming the inclined light incidence surface comprises cutting with machine processing.

9. The method according to claim 7, wherein an operation of forming the inclined light incidence surface comprises first cutting a P-type semiconductor of the epitaxial layer to a predetermine depth with machine processing and then applying a chemical agent to carryout etching to form the light incidence surface.

10. The method according to claim 7, further comprising forming an anti-reflection layer on the epitaxial layer, the anti-reflection layer comprising a metallic alloy.

11. The method according to claim 8, further comprising forming an anti-reflection layer on the epitaxial layer, the anti-reflection layer comprising a metallic alloy.

12. The method according to claim 9, further comprising forming an anti-reflection layer on the epitaxial layer, the anti-reflection layer comprising a metallic alloy.

13. The method according to claim 10, wherein the metallic alloy comprises Ti, Pt, Au and AuGeNi.

14. The photodiode according to claim 11, wherein the metallic alloy comprises Ti, Pt, Au and AuGeNi.

15. The photodiode according to claim 12, wherein the metallic alloy comprises Ti, Pt, Au and AuGeNi.

16. A method for manufacturing a photodiode, comprising:
providing a substrate;
forming an etch stop layer on the substrate;
forming an epitaxial layer on the etch stop layer; and
applying a chemical agent to etch a lateral side of the substrate to form a light incidence surface that is inclined, the light incidence surface forming an angle of 45 degrees or 60 degrees with respect to a normal of the substrate.

17. The method according to claim 16, further comprising forming an anti-reflection layer on the epitaxial layer, the anti-reflection layer comprising a metallic alloy.

18. The method according to claim 17, wherein the metallic alloy comprises Ti, Pt, Au and AuGeNi.
